(19) United States
(12) Patent Application Publication
(10) Pub. No.: US 2004/0041214 A1
(43) Pub. Date: Mar. 4, 2004

(54) One F2 memory cell, memory array, related devices and methods

(76) Inventor: Kirk D. Prall, Boise, ID (US)

Correspondence Address: Attn: Thomas W. Leffert, Leffert Jay & Polglaze, P.A., P. O. Box 581009, Minneapolis, MN, 55458-1009, US

(21) Appl. No.: 10/232,411

(22) Filed: Aug. 29, 2002

(51) Int. Cl. H01L 29/76

(52) U.S. Cl. 257/390

(57) ABSTRACT

An array of memory cells configured to store at least one bit per one F² includes substantially vertical structures providing an electronic memory function spaced apart a distance equal to one half of a minimum pitch of the array. The structures providing the electronic memory function are configured to store more than one bit per gate. The array also includes electrical contacts to the memory cells including the substantially vertical structures.

### TECHNICAL FIELD

This invention relates to a one F² memory cell, arrays of such memory cells, electronic devices employing such memory cells and arrays, and methods related to such memory cells.

### BACKGROUND OF THE INVENTION

Various types of memory devices are used in electronic systems. Some types of memory device, such as DRAM (dynamic random access memory) provide large amounts of readable and writable data storage with modest power budget and in favorably small form factor, but are not as fast as other types of memory devices and provide volatile data storage capability. Volatile data storage means that the memory must be continuously powered in order to retain data, and the stored data are lost when the power is interrupted. Nonvolatile memories are capable of retaining data without requiring electrical power.

Other types of memory can provide read-only or read-write capabilities and non-volatile data storage, but are much slower in operation. These include CD-ROM devices, CD-WORM devices, magnetic data storage devices (hard discs, floppy discs, tapes and so forth), magneto-optical devices and the like.

Still other types of memory provide very high speed operation but also demand high power budgets. Static RAM or SRAM is an example of such memory devices.

In most computer systems, different memory types are blended to selectively gain the benefits that each technology can offer. For example, read-only memories or ROM, EEPROM and the like are typically used to store limited amounts of relatively infrequently-accessed data such as a basic input-output system. These memories are employed to store data that, in response to a power ON situation, configure a processor to be able to load larger amounts of software such as an operating system from a high capacity non-volatile memory device such as a hard drive. The operating system and application software are typically read from the high capacity memory and corresponding images are stored in DRAM.

As the processor executes instructions, some types of data may be repeatedly fetched from memory. As a result, some SRAM or other high speed memory is typically provided as “cache” memory in conjunction with the processor and may be included on the processor integrated circuit or chip and/or very near it.

Several different kinds of memory device are involved in most modern computing devices, and in many types of appliances that include automated and/or programmable features (home entertainment devices, telecommunications devices, automotive control systems etc.). As system and software complexity increase, need for additional memory increases. Desire for portability, computation power and/or practicality result in increased pressure to reduce both power consumption and circuit area per bit.

DRAMs have been developed to very high capacities in part because the memory cells can be manufactured to have a very small area, and the power draw per cell can also be made quite small. In turn, this allows memory integrated circuits to be made that incorporate millions of memory cells in each chip. Typical one-transistor, one-capacitor DRAM memory cells can be produced to have extremely small areal requirements.

Such areas are often equal to about 3F×2F, or less, where “F” is defined as equal to one-half of minimum pitch (see FIG. 4, infra). Minimum pitch (i.e., “P”) is defined as equal to the smallest distance of a line width (i.e., “W”) plus width of a space immediately adjacent the line on one side of the line between the line and a next adjacent line in a repeated pattern within the array (i.e., “S”). Thus, in many implementations, the consumed area of a given DRAM cell is no greater than about 8F².

However, because DRAMs are volatile memory devices, they require “refresh” operations. In a refresh operation, data are read out of each memory cell, amplified and written back into the DRAM. As a first result, the DRAM circuit is usually not available for other kinds of memory operations during the refresh operation. Additionally, refresh operations are carried out periodically, resulting in times during which data cannot be readily extracted from or written to DRAMs. As a second result, some amount of electrical power is always needed to store data in DRAM devices.

As a third result, boot operations for computers such as personal computers involve a period during which the computer cannot be used following power ON initiation. During this period, operating system instructions and associated data, and application instructions and associated data, are read from relatively slow, non-volatile memory, such as a conventional disc drive, are decoded by the processing unit and the resultant instructions and associated data are loaded into modules incorporating relatively rapidly-accessible, but volatile, memory such as DRAM. Other consequences flow from the properties of the memory systems included in various electronic devices and the increasingly complex software employed with them, however, these examples serve to illustrate ongoing needs.

Needed are methods and apparatus relating to non-volatile memory providing high areal data storage capacity, reprogrammability, low power consumption and relatively high data access speed.

### SUMMARY OF THE INVENTION

In a first aspect, the present invention includes a method for making an array of memory cells configured to store at least one bit per one F². The method includes doping a first region of a semiconductor substrate and incising the substrate to provide an array of substantially vertical edge surfaces. Pairs of the edge surfaces face one another and are spaced apart a distance equal to one half of a pitch of the array of edges. The method also includes doping second regions between the pairs of edge surfaces and disposing respective structures each providing an electronic memory function on at least some respective ones of the edge surfaces. The method also includes establishing electrical contacts to the first and second regions.

In another aspect, the present invention includes a method for making an array of memory cells configured to store at least one bit per one F². The method includes disposing substantially vertical structures providing an electronic memory function spaced apart a distance equal to one half of a minimum pitch of the array and establishing electrical contacts to memory cells including the vertical structures.

In a further aspect, the present invention includes an array of memory cells configured to store at least one bit per one F² formed using vertical structures providing an electronic memory function spaced apart a distance equal to one half of a minimum pitch of the array. The structures providing the electronic memory function are configured to store more than one bit per gate. The array also includes electrical contacts to the memory cells including the vertical structures.

### BRIEF DESCRIPTION OF THE DRAWINGS

Embodiments of the invention are described below with reference to the following accompanying drawings.

FIG. 1 is a simplified side view, in section, of a semiconductor substrate portion at one stage in processing, in accordance with an embodiment of the present invention.

FIG. 2 is a simplified side view, in section, of the substrate portion of FIG. 1 at a later stage in processing, in accordance with an embodiment of the present invention.

FIG. 3 is a simplified side view, in section, of the substrate portion of FIG. 2 at a later stage in processing, in accordance with an embodiment of the present invention.

FIG. 4 is a simplified plan view of a substrate portion showing a portion of a memory cell array, in accordance with an embodiment of the present invention.

FIG. 5 is a simplified side view, in section, illustrating a relationship between the structures of FIGS. 1-3 and the plan view of FIG. 4, in accordance with an embodiment of the present invention.

FIG. 6 is a simplified plan view of a memory cell array illustrating an interconnection arrangement for the memory cell array of FIG. 4, in accordance with an embodiment of the present invention.

FIG. 7 is a simplified side view, in section, taken along section lines 7-7 of FIG. 6, illustrating part of an interconnection arrangement in accordance with an embodiment of the present invention.

FIG. 8 is a simplified side view, in section, taken along section lines 8-8 of FIG. 6, illustrating part of an interconnection arrangement in accordance with an embodiment of the present invention.

FIG. 9 is a simplified block diagram of a computer employing the inventive memory array associated with FIGS. 1-8, in accordance with an embodiment of the present invention.

### DETAILED DESCRIPTION OF THE PREFERRED EMBODIMENTS

This disclosure of embodiments in accordance with the present invention is submitted in furtherance of the constitutional purposes of the U.S. Patent Laws “to promote the progress of science and useful arts” (Article 1, Section 8).

As used herein, the terms “semiconductor substrate” or “semiconductive substrate” are defined to mean any construction comprising semiconductive material, including, but not limited to, bulk semiconductive materials such as a semiconductive wafer (either alone or in assemblies comprising other materials thereon), and semiconductive material layers (either alone or in assemblies comprising other materials). The term “substrate” refers to any supporting structure, including, but not limited to, the semiconductive substrates described above.

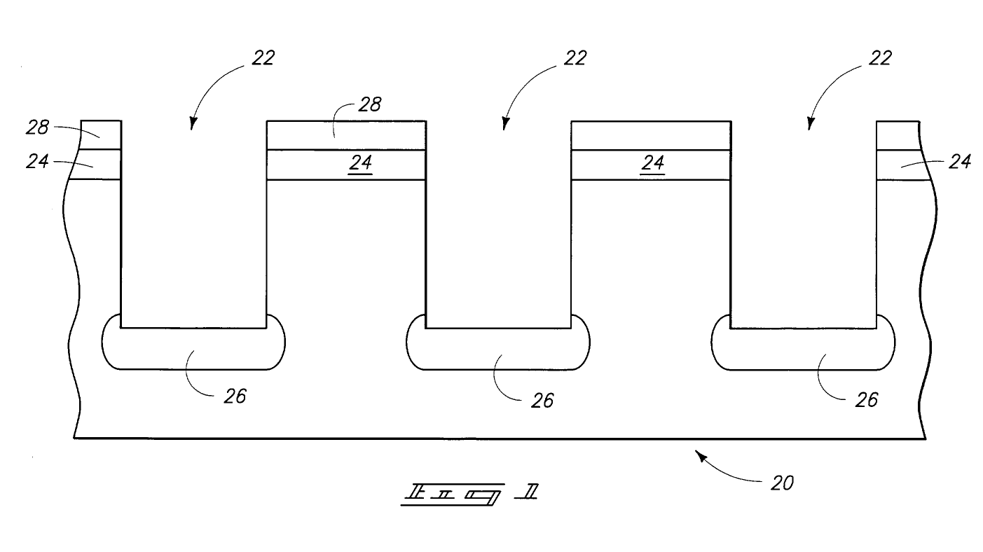

FIG. 1 is a simplified side view, in section, of a semiconductor substrate portion 20 at one stage in processing, in accordance with an embodiment of the present invention. The portion 20 includes etched or incised recesses 22, doped regions 24 and 26 and caps 28. The etched recesses 22 form trenches extending along an axis into and out of the page of FIG. 1.

In one embodiment, the doped regions 24 are implanted n+ regions. In one embodiment, the doped regions 24 are formed by a blanket implant. In one embodiment, the caps 28 are dielectric caps and may be formed using conventional silicon nitride and conventional patterning techniques. In one embodiment, the etched recesses 22 are then etched using conventional plasma etching techniques. In one embodiment, the doped regions 26 are then doped by implantation to form n+ regions. The etched or incised recesses 22 may be formed by plasma etching, laser-assisted techniques or any other method presently known or that may be developed. In one embodiment, the recesses 22 are formed to have substantially vertical sidewalls relative to a top surface of the substrate portion 20. In one embodiment, substantially vertical means at 90 degrees to the substrate surface, plus or minus ten degrees.

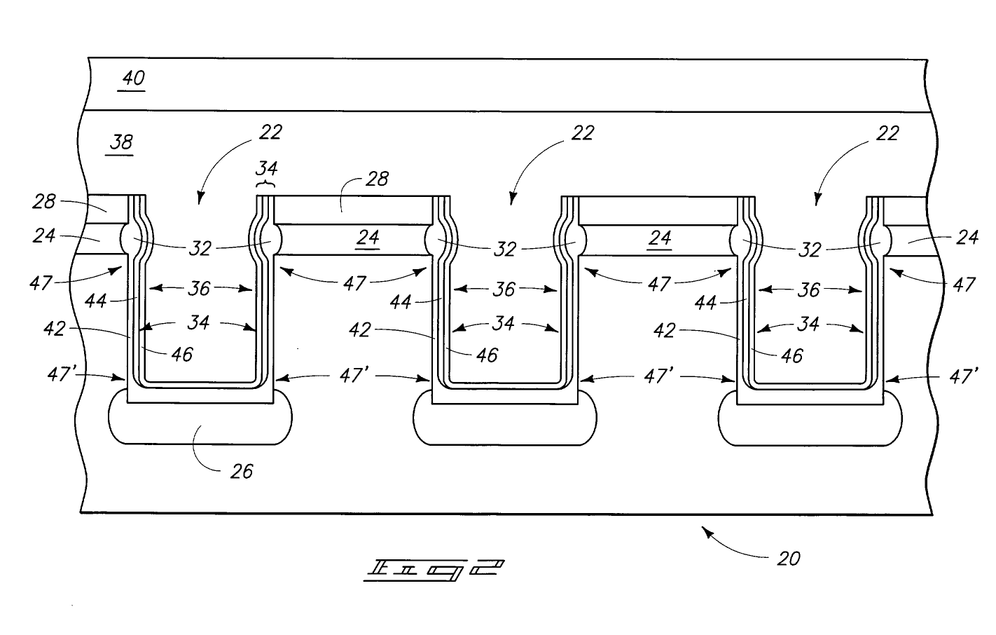

FIG. 2 provides a simplified side view, in section, of the substrate portion 20 of FIG. 1 at a later stage in processing, in accordance with an embodiment of the present invention. The portion 20 of FIG. 2 includes thick oxide regions 32, ONO regions 34 formed on sidewalls 36 of the recesses 22, gate material 38 and a conductive layer 40. In one embodiment, the gate material 38 comprises conductively-doped polycrystalline silicon.

In one embodiment, conventional techniques are employed to oxidize the doped regions 24 and 26 preferentially with respect to sidewalls 36. As a result, the thick oxide regions 32 are formed at the same time as a thinner oxide 42 on the sidewalls 36. These oxides also serve to isolate the doped regions 24 and 26 from what will become transistor channels along the sidewalls 36. Other techniques for isolation may be employed. For example, in one embodiment, high density plasma grown oxides may be employed. In one embodiment, spacers may be employed.

In one embodiment, conventional techniques are then employed to provide a nitride layer 44 and an oxide layer 46, as is described, for example, in “NROM: A Novel Localized Trapping, 2 Bit Nonvolatile Memory Cell”, by Boaz Eitan et al., IEEE Electron Device Letters, Vol. 21, No. 11, November 2000, pp. 543-545, IEEE Catalogue No. 0741-3106/00, or in “A True Single-Transistor Oxide-Nitride-Oxide EEPROM Device” by T. Y. Chan et al., IEEE Electron Device Letters, Vol. EDL-8, No. 3, March, 1987, pp. 93-95, IEEE Catalogue No. 0741-3106/87/0300-0093.

In one embodiment, the thin oxide 42, nitride layer 44 and oxide layer 46 combine to form the ONO layer 34, such as is employed in SONOS devices, while the polysilicon 38 forms a control gate. In operation, application of suitable electrical biases to the doped regions 24, 26 and the control gate 38 cause hot majority charge carriers to be injected into the nitride layer 44 and become trapped, providing a threshold voltage shift and thus providing multiple, alternative, measurable electrical states representing stored data. “Hot” charge carriers are not in thermal equilibrium with their environment. In other words, hot charge carriers represent a situation where a population of high kinetic energy charge carriers exist. Hot charge carriers may be electrons or holes.

SONOS devices are capable of storing more than one bit per gate 38. Typically, the hot carriers are injected into one side 47 or 47′ of the ONO layer 34, adjacent a contact, such as the region 24 or the region 26, that provides a high electrical field.

By reversing the polarity of the potentials applied to the regions 24 and 26, charge may be injected into the other side 47′ or 47 of the ONO layer 34. Thus, four electronically-discriminable and distinct states can be easily provided with a single gate 38. As a result, the structure shown in FIG. 2 is capable of storing at least four bits per gate 38.

FIG. 3 is a simplified side view, in section, of the substrate portion 20 of FIG. 1 at an alternative stage in processing, in accordance with an embodiment of the present invention. The embodiment shown in FIG. 3 includes the oxide regions 32 and 42, but a floating gate 48 is formed on the thin oxide region 42. A conventional oxide or nitride insulator 49 is formed on the floating gate 48, followed by deposition of gate material 38. Floating gate devices are known and operate by injecting hot charge carriers, which may comprise electrons or holes, into the floating gate 48.

Floating gate devices can be programmed to different charge levels that can be electrically distinct and distinguishable. As a result, it is possible to program more data than one bit into each floating gate device, and each externally addressable gate 38 thus corresponds to more than one stored bit. Typically, charge levels of 0, Q, 2Q and 3Q might be employed, where Q represents some amount of charge corresponding to a reliably-distinguishable output signal.

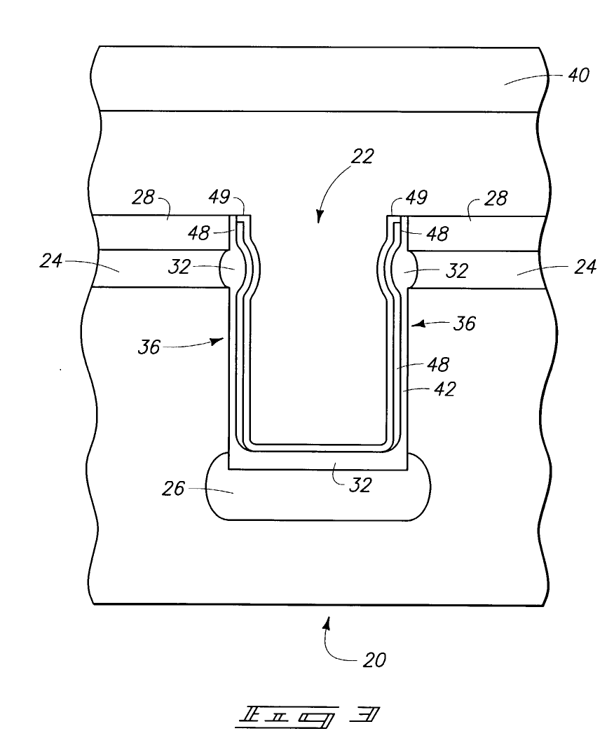

FIG. 4 is a simplified plan view of a substrate portion showing a portion of a memory cell array 50, in accordance with an embodiment of the present invention. FIG. 4 also provides examples of pitch P, width W, space S and minimum feature size F, as described in the Background. An exemplary memory cell area 52 can be seen to be about one F², in contrast to prior art memory cells. Wordlines 54 are formed from the conductive layer 40, and bitlines 56 and 58 are formed.

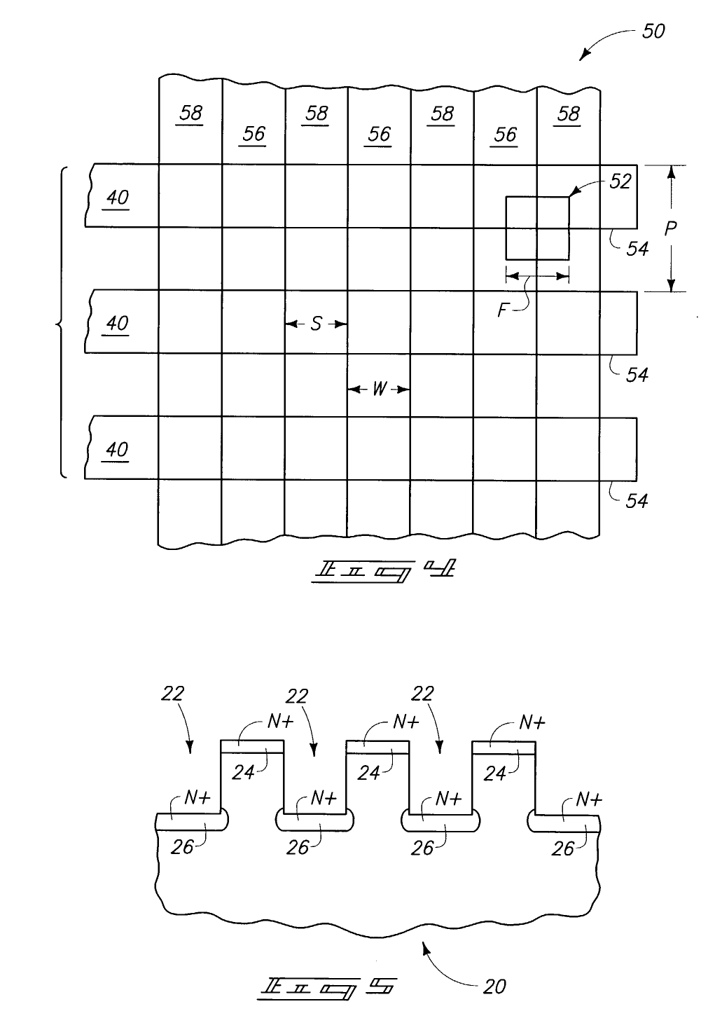

FIG. 5 is a simplified side view, in section, illustrating a relationship between the structures of FIGS. 1-3 and the plan view of FIG. 4, in accordance with an embodiment of the present invention. The trenches 22 correspond to bitlines 56 and 58, as is explained below in more detail with reference to FIGS. 6-8.

The density of memory arrays such as that described with reference to FIGS. 1-5 can require interconnection arrangements that differ from prior art memory arrays. One embodiment of a new type of interconnection arrangement useful with such memory systems is described below with reference to FIGS. 6-8.

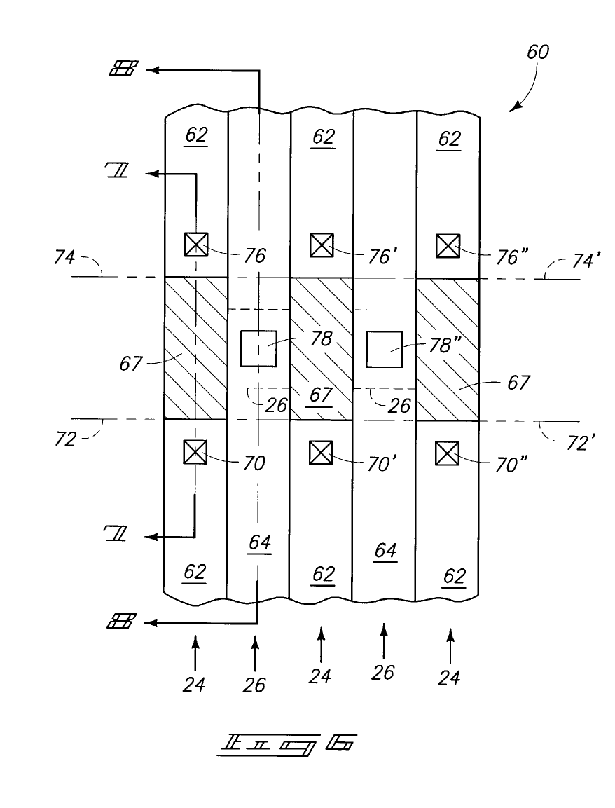

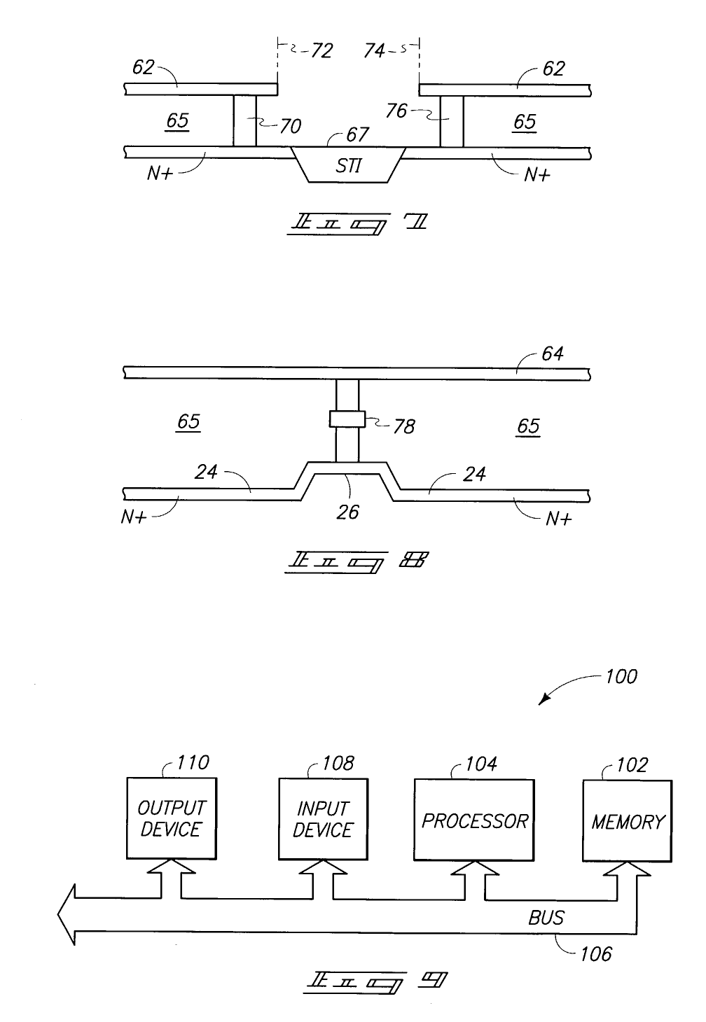

FIG. 6 is a simplified plan view illustrating an interconnection arrangement 60 for the memory cell array 50 of FIG. 4, in accordance with an embodiment of the present invention. The interconnection arrangement 60 includes multiple patterned conductive layers 62 and 64, separated by conventional interlevel dielectric material 65 (FIGS. 7 and 8). The views in FIGS. 6-8 have been simplified to show correspondence with the other Figs. and to avoid undue complexity. Shallow trench isolation regions 67 isolate selected portions from one another.

FIG. 7 is a simplified side view, in section, taken along section lines 7-7 of FIG. 6, illustrating part of an interconnection arrangement in accordance with an embodiment of the present invention.

FIG. 8 is a simplified side view, in section, taken along section lines 8-8 of FIG. 6, illustrating part of an interconnection arrangement in accordance with an embodiment of the present invention.

With reference to FIGS. 6-8, the patterned conductive layer 62 extends upward to nodes 70, 70′, 70″ and establishes electrical communication between the conductive layers 62 and selected portions of the doped region 24. The patterned conductive layer 62 stops at the line denoted 72, 72′.

Similarly, other portions of the patterned conductive layer 62 extend from the line denoted 74, 74′ and extend upward, providing electrical communication from nodes 76, 76′, 76″ to other circuit elements. The nodes 76, 76′, 76″ provide contact to selected portions of the doped region 24.

In contrast, patterned conductive layers 64 extend from top to bottom of FIG. 6 and electrically couple to nodes 78, 78′ and thus to doped region 26.

Such is but on example of a simplified interconnection arrangement suitable for use with the memory devices of FIGS. 1-5. Other arrangements are possible.

FIG. 9 is a simplified block diagram of a computer 100 employing the inventive memory array associated with FIGS. 1-8, in accordance with an embodiment of the present invention. The computer 100 includes a memory 102, including memory cells in accordance with the present invention, a processor 104 and a bus 106 coupling the memory 102 and processor 104. An input device 108, which may be a tactile input device, is coupled to the bus 106, and an output device 110 is coupled to the bus 106.

The computer 100 may be employed in a broad variety of settings. For example, the tactile input device 108 could include voice and speech recognition capabilities, or could be part of a dashboard or control system for a vehicle, or could be a keyboard or mouse or combination thereof, or could be a dialing instruction input device for a telecommunications device such as a telephone or cellular telephone, or could be associated with some other type of appliance, such as a television, a washing machine or refrigerator, microwave oven or the like.

Similarly, the output device 110 could be a visual display that is part of a dashboard or other control system for a vehicle, or an alphanumeric display for a computer (e.g., CRT, flat panel TFT display or the like), or a visual display associated with a telecommunications device, or could be associated with a home or industrial appliance. The output device 110 may include other capabilities for communication, such as an annunciator or speaker, Braille signaling capability and the like.

In operation, a command sequence is initiated, either by a user associated with the device or a remote party (e.g., a caller using a telephone or a service provider initiating a data stream). The processor 104 executes the command sequence in accordance with instructions stored in the memory 102, using portions of the memory 102 for temporary storage of intermediate results and other portions of the memory 102 for longer-term storage of other results or data (such as telephone numbers, elapsed miles etc.). Visual, aural and other types of output signals may be generated to advise the user of status of various aspects of the system in which the computer 100 is resident.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

1. A method for making an array of memory cells configured to store at least one bit per one F² comprising:
doping a first region of a semiconductor substrate;
incising the substrate to provide an array of edges having substantially vertical edge surfaces, pairs of the edge surfaces facing one another and spaced apart a distance equal to one half of a pitch of the array of edges;
doping second regions between the pairs of edge surfaces;
disposing respective structures each providing an electronic memory function on at least some respective ones of the edge surfaces; and
establishing electrical contacts to the first and second regions.

2. The method of claim 1, wherein disposing comprises:
forming ONO structures on at least some respective ones of the edge surfaces; and
creating respective gates on the ONO structures.

3. The method of claim 1, wherein disposing comprises:
forming ONO structures on at least some respective ones of the edge surfaces; and
creating respective gates on the ONO structures, wherein forming ONO structures comprises:
growing silicon dioxide from silicon comprising the edge surfaces;
forming a silicon nitride layer on the silicon dioxide; and
forming silicon dioxide on the silicon nitride.

4. The method of claim 1, wherein disposing comprises forming respective polysilicon gates on respective ones of the surface edges.

5. The method of claim 1, wherein disposing comprises:
forming a first gate dielectric on the surface edge;
forming a floating gate on the first gate dielectric;
forming a second gate dielectric on the floating gate; and
forming a control gate on the second gate dielectric.

6. The method of claim 1, wherein disposing comprises disposing structures comprising gates each configured to store more than one bit per gate.

7. The method of claim 1, wherein disposing comprises:
forming a first gate dielectric on the surface edge;
forming a floating gate on the first gate dielectric, wherein the floating gate is configured to store more than one bit per floating gate;
forming a second gate dielectric on the floating gate; and
forming a control gate on the second gate dielectric.

8. The method of claim 1, wherein disposing comprises:
forming ONO structures on at least some of the edge surfaces; and
creating respective gates on the ONO structures, wherein the structures providing the electronic memory function are configured to store more than one bit per gate.

9. The method of claim 1, wherein the semiconductor substrate comprises silicon.

10. A method for making an array of memory cells configured to store at least one bit per one F² comprising:
disposing non-horizontal structures providing an electronic memory function spaced apart a distance equal to one half of a minimum pitch of the array; and
establishing electrical contacts to memory cells including the non-horizontal structures.

11. The method of claim 10, further comprising:
incising the substrate to provide an array of substantially vertical edge surfaces, pairs of the edge surfaces facing one another and spaced apart a distance equal to one half of a minimum pitch of the array of edges; and
doping second regions between the pairs of edge surfaces, wherein:
disposing comprises disposing the non-horizontal structures on the substantially vertical edge surfaces; and
establishing electrical contacts includes establishing electrical contacts to the first and second regions and to the non-horizontal structures.

12. The method of claim 11, wherein disposing the non-horizontal structures on the substantially vertical edge surfaces comprises:
forming ONO structures on at least some of the edge surfaces; and
creating respective gates on the ONO structures, wherein the structures providing the electronic memory function are configured to store more than one bit per gate.

13. The method of claim 11, wherein disposing the non-horizontal structures on the substantially vertical edge surfaces comprises:
forming ONO structures on at least some of the edge surfaces; and
creating respective gates on the ONO structures.

14. The method of claim 10, wherein the structures providing the electronic memory function are configured to store more than one bit per gate.

15. The method of claim 11, wherein disposing non-horizontal structures comprises:
forming a first gate dielectric on the edge surfaces;
forming a floating gate on the first gate dielectric, wherein the floating gate is configured to store more than one bit per floating gate;
forming a second gate dielectric on the floating gate; and
forming a control gate on the second gate dielectric.

16. The method of claim 11, wherein disposing the non-horizontal structures on the substantially vertical edge surfaces comprises:
forming a first gate dielectric on the surface edge;
forming a floating gate on the first gate dielectric;
forming a second gate dielectric on the floating gate; and
forming a control gate on the second gate dielectric.

17. The method of claim 11, wherein disposing comprises forming respective polysilicon gates on the edge surfaces.

18. The method of claim 10, wherein disposing comprises forming respective polysilicon gates.

19. The method of claim 10, wherein disposing comprises disposing a structure that is configured to provide an electronic memory function by storing holes.

20. The method of claim 10, wherein disposing non-horizontal structures comprises disposing substantially vertical structures.

21. A method for making an array of memory cells configured to store at least one bit per one F² comprising:
disposing non-horizontal structures providing an electronic memory function spaced apart a distance equal to one half of a minimum pitch of the array, wherein the structures providing the electronic memory function are configured to store more than one bit per gate; and
establishing electrical contacts to memory cells including the non-horizontal structures.

22. The method of claim 21, wherein disposing non-horizontal structures comprises disposing substantially vertical structures.

23. An array of memory cells configured to store at least one bit per one F² comprising:
memory cells arranged in rows and columns each coupled to respective row and column decoding circuitry, wherein each memory cell comprises:
first doped regions formed on a surface of a semiconductor substrate;
an array of incisions formed into the substrate to provide an array of substantially vertical edge surfaces, pairs of the edge surfaces facing one another and spaced apart a distance equal to one half of a pitch of the array of edge surfaces;
second doped regions formed between the pairs of edge surfaces;
respective structures each providing an electronic memory function disposed on at least some respective ones of the edge surfaces; and
electrical contacts to the first and second regions and to the structures providing the electronic memory function.

24. The array of claim 23, wherein the structures providing an electronic memory function each comprise:
ONO structures formed on at least some respective ones of the edge surfaces; and
respective gates formed on the ONO structures.

25. The array of claim 23, wherein the structures providing an electronic memory function each comprise:
ONO structures each formed on at least some respective ones of the edge surfaces; and
respective gates formed on the ONO structures, wherein the ONO structures comprise:
silicon dioxide grown from silicon comprising the edge surfaces;
silicon nitride formed on the silicon dioxide; and
silicon dioxide formed on the silicon nitride.

26. The array of claim 23, wherein the structures providing an electronic memory function each comprise respective polysilicon gates formed on respective ones of the surface edges.

27. The array of claim 23, wherein the structures providing an electronic memory function each comprise:
a first gate dielectric formed on the edge surfaces;
a floating gate formed on the first gate dielectric;
a second gate dielectric formed on the floating gate; and
a control gate formed on the second gate dielectric.

28. The array of claim 23, wherein the structures providing an electronic memory function each comprise structures each configured to store more than one bit per gate.

29. The array of claim 23, wherein the structures providing an electronic memory function each comprise:
a first gate dielectric formed on the edge surfaces;
a floating gate formed on the first gate dielectric, wherein the floating gate is configured to store more than one bit per floating gate;
a second gate dielectric formed on the floating gate; and
a control gate formed on the second gate dielectric.

30. The array of claim 23, wherein the structures providing an electronic memory function each comprise:
ONO structures formed on at least some of the edge surfaces; and
respective gates formed on the ONO structures, wherein the structures providing the electronic memory function are configured to store more than one bit per gate.

31. The array of claim 23, wherein the semiconductor substrate comprises silicon.

32. An array of memory cells configured to store at least one bit per one F² comprising:
memory cells arranged in rows and columns each coupled to respective row and column decoding circuitry, wherein each memory cell comprises:
substantially vertical structures providing an electronic memory function spaced apart a distance equal to one half of a minimum pitch of the array; and
electrical contacts to the memory cells including the substantially vertical structures.

33. The array of claim 32, further comprising:
incisions in the substrate that provide an array of substantially vertical edge surfaces, pairs of the edge surfaces facing one another and spaced apart a distance equal to one half of a minimum pitch of the array of edge surfaces; and
second doped regions formed between the pairs of edge surfaces, wherein:
the substantially vertical structures are formed on the substantially vertical edge surfaces; and
the electrical contacts include electrical contacts to the first and second regions and to the substantially vertical structures.

34. The array of claim 33, wherein the substantially vertical structures on the substantially vertical edge surfaces each comprise:
ONO structures formed on at least some of the edge surfaces; and
respective gates formed on the ONO structures, wherein the structures providing the electronic memory function are configured to store more than one bit per gate.

35. The array of claim 33, wherein disposing the substantially vertical structures on the substantially vertical edge surfaces comprises:
ONO structures formed on at least some of the edge surfaces; and
respective gates formed on the ONO structures.

36. The array of claim 32, wherein the structures providing the electronic memory function are configured to store more than one bit per gate.

37. The array of claim 33, wherein each substantially vertical structure comprises:
a first gate dielectric formed on the edge surfaces;
a floating gate formed on the first gate dielectric, wherein the floating gate is configured to store more than one bit per floating gate;
a second gate dielectric formed on the floating gate; and
a control gate formed on the second gate dielectric.

38. The array of claim 33, wherein each of the substantially vertical structures on the substantially vertical edge surfaces comprises:
a first gate dielectric formed on the surface edge;
a floating gate formed on the first gate dielectric;
a second gate dielectric formed on the floating gate; and
a control gate formed on the second gate dielectric.

39. The array of claim 33, wherein the substantially vertical structures each include respective polysilicon gates formed on the edge surfaces.

40. The array of claim 32, wherein the substantially vertical structures comprise respective polysilicon gates.

41. The array of claim 32, wherein the substantially vertical structures are configured to provide an electronic memory function by storing holes.

42. An array of memory cells configured to store at least one bit per one F² comprising:
substantially vertical structures providing an electronic memory function spaced apart a distance equal to one half of a minimum pitch of the array, wherein the structures providing the electronic memory function are configured to store more than one bit per gate; and
electrical contacts to the memory cells including the substantially vertical structures.

43. A method of programming a memory cell in an array of memory cells configured to store at least one bit per F², comprising:
coupling a first electrode to a first potential, where the first electrode is coupled to one of a first doped region disposed on a surface of a semiconductor substrate and a second doped region disposed on a bottom surface of one of a plurality of trenches formed in the substrate surface;
coupling a second electrode to a second potential, where the second electrode is coupled to another of the first and second doped regions;
coupling a third electrode to a gate formed adjacent one of a plurality substantially vertical structures each providing electronic memory functions and that are spaced apart a distance equal to one half of a minimum pitch of the array on opposing sidewalls of the plurality of trenches between the first and second doped regions, wherein the structures providing the electronic memory functions are configured to store more than one bit per gate; and
storing charge carriers in the one substantially vertical structure.

44. The method of claim 43, wherein the substantially vertical structure comprises an ONO structure, the charge carriers comprise electrons and the charge carriers are stored at an edge of the ONO structure that is disposed adjacent one or the other of the first and second doped regions.

45. The method of claim 43, wherein the substantially vertical structure comprises an ONO structure and the charge carriers comprise electrons, and wherein the ONO structure is configured to be able to store charge at at least one of edges of the ONO structures that are disposed adjacent the first and second doped regions.

46. The method of claim 43, further comprising exposing the ONO structure to conditions effective to remove charge carriers stored in the ONO structure.

47. The method of claim 43, wherein storing charge carriers in the one substantially vertical structure comprises storing charge carriers at a first physical location in the one substantially vertical structure, and further comprising reversing the first and second potentials to store charge carriers at a second physical location within the one substantially vertical structure.

48. An array of memory cells configured to store at least one bit per one F² comprising:
memory cells arranged in rows and columns each coupled to respective row and column decoding circuitry, wherein each memory cell comprises:
spaced-apart structures providing an electronic memory function separated by a distance equal to one half of a minimum pitch of the array; and
electrical contacts to the memory cells including the spaced-apart structures.

49. The array of claim 48, wherein the spaced apart structure comprise substantially vertical structures.

50. The array of claim 49, further comprising:
incisions in the substrate that provide an array of substantially vertical edge surfaces, pairs of the edge surfaces facing one another and spaced apart a distance equal to one half of a minimum pitch of the array of edge surfaces; and
second doped regions formed between the pairs of edge surfaces, wherein:
the substantially vertical structures are formed on the substantially vertical edge surfaces; and
the electrical contacts include electrical contacts to the first and second regions and to the substantially vertical structures.

51. The array of claim 50, wherein the substantially vertical structures on the substantially vertical edge surfaces each comprise:
ONO structures formed on at least some of the edge surfaces; and
respective gates formed on the ONO structures, wherein the structures providing the electronic memory function are configured to store more than one bit per gate.
